(19) United States
(12) Patent Application Publication
(10) Pub. No.: US 2011/0128988 A1
(43) Pub. Date: Jun. 2, 2011

(54) TEMPERATURE CONTROL OF CONDUCTION-COOLED DEVICES DURING TESTING AT HIGH TEMPERATURES

(75) Inventor: Christopher John OTTE, Hollis, NH (US)

(73) Assignee: JUNIPER NETWORKS INC., Sunnyvale, CA (US)

(21) Appl. No.: 12/629,675

(22) Filed: Dec. 2, 2009

(51) Int. Cl. G01N 25/00; G05D 23/00; G01R 31/00

(52) U.S. Cl. 374/57; 165/287

(57) ABSTRACT

A high temperature testing system for an electronic device may include a testing chamber in which the temperature of ambient air in the testing chamber may be maintained at a desired testing temperature and the surface temperature of the electronic device may be maintained at a second desired testing temperature, where the ambient air temperature and the surface temperature of the electronic device may be set to be equal to one another. In one implementation, a system may control operation of a fan based on the surface temperature of the electronic device. The system may further include a testing apparatus that includes a heat exchanger connected to an inlet hose such that blown air is passed over the heat exchanger to cool the heat exchanger. A temperature sensor may be attached to the heat exchanger and may generate the temperature signal.

### BACKGROUND

Temperature can be an important factor in the operation of electronic devices. At too high a temperature, circuits may fail. The practical upper temperature limit of an electronic device may be determined by many factors, such as the limit of the semiconductor material, interconnections, and packaging.

A designer of an electronic device may be given a specification that describes the maximum upper temperature limit at which the device is required to reliably operate. The designer may wish or be required to test the device at the maximum upper temperature limit.

Because electronic devices generate heat when operating, it may be necessary to cool the electronic device in order to keep the temperature of the device below the upper temperature. One technique for cooling an electronic device may rely on conduction cooling in which a thermally conductive solid is used to conduct heat away from the electronic device. One advantage of conduction cooling is that forced air (which can contain contaminates) is not required to cool the electronics. The heat is transported (conducted) away and eventually dissipated to the surrounding atmosphere.

When temperature testing an electronic device that is designed to be implemented in a conduction-cooled system, it may be desirable to test the operation of the electronic device at the upper temperature limit in a test environment that simulates the final deployed system for the electronic device as closely as possible.

### SUMMARY

One implementation is directed to a system for testing an electronic device. The system may include a air mover unit, a testing apparatus, and a testing chamber. The air mover unit may include a fan; logic to control operation of the fan based on a temperature signal received by the air mover unit, the temperature signal indicating a temperature associated with the testing apparatus or the electronic device; and an outlet hose connected to an output of the fan to carry air blown by the fan. The testing apparatus may include an inlet hose connected to receive the air blown through the outlet hose; a heat exchanger connected to the inlet hose such that the blown air is passed over the heat exchanger to cool the heat exchanger, the heat exchanger additionally configured to hold the electronic device that is being tested; and a temperature sensor attached to the heat exchanger, the temperature sensor generating the temperature signal that is received by the air mover unit. The testing chamber may include a chamber to hold the testing apparatus and a heater to heat the testing chamber to a user designated temperature during testing of the electronic device.

Another implementation is directed to a method for testing an electronic device. The method may include maintaining a first air temperature, within a testing chamber that includes the electronic device, the electronic device including a heat exchanger to dissipate heat generated by the electronic device. The method may further include setting, in a control unit, a desired surface temperature of the electronic device and controlling, by the control unit, cooling of the heat exchanger to maintain the electronic device at the desired temperature of the electronic device, the cooling including blowing room temperature air from outside of the testing chamber over the heat exchanger, where the temperature of the room temperature air is less than the first air temperature. The method may further include testing operation of the electronic device while the electronic device is within the testing chamber and transmitting results of the testing of the electronic device to a computing device located externally to the testing chamber.

In another implementation, a device may include a baseplate; a rail attached to the baseplate, the rail being formed of thermally conductive material, the rail being formed to secure a printed circuit board (PCB) case; a heat exchanger connected to the rail and the baseplate, the heat exchanger being formed of thermally conductive material; a backplane connected to the baseplate, the backplane include an electrical connection to form an electrical interface with the PCB case when the PCB case is inserted into the rail; an inlet hose connected to deliver air blown from an external source to the heat exchanger; and a temperature sensor attached to the heat exchanger, the temperature sensor generating a temperature signal that is used to control an amount of air delivered via the inlet hose.

### BRIEF DESCRIPTION OF THE DRAWINGS

The accompanying drawings, which are incorporated in and constitute a part of this specification, illustrate one or more embodiments described here and, together with the description, explain these embodiments. In the drawings:

FIG. 1 is a diagram of an exemplary system in which concepts described herein may be implemented;

FIG. 2 is a diagram illustrating an exemplary implementation of the control equipment shown in FIG. 1;

FIG. 3 is a diagram illustrating an exemplary implementation of the testing apparatus shown in FIG. 1;

FIGS. 4A-4C are diagrams illustrating an exemplary implementation of a package that includes a device under test;

FIG. 5 is a block diagram illustrating an exemplary implementation of a fan unit;

FIG. 6 is a flow chart illustrating exemplary operations for performing a high temperature test of an electronic device;

FIGS. 7A and 7B are diagrams conceptually illustrating heat flow for a testing apparatus; and

FIG. 8 is a diagram schematically illustrating an exemplary complete test system.

### DETAILED DESCRIPTION

The following detailed description refers to the accompanying drawings. The same reference numbers in different drawings may identify the same or similar elements. Also, the following detailed description does not limit the invention.

As described herein, a testing platform for a conductive-cooled electronic device may include a testing chamber in which the temperature of the ambient air in the testing chamber may be maintained at a desired testing temperature. The device to be tested may be placed inside the testing chamber. A heat exchanger may be attached to the device to assist in keeping the device at the desired temperature. A temperature control mechanism, such as variable speed fans that blows external air over the heat exchanger, may be used to keep the heat exchanger at the testing temperature.

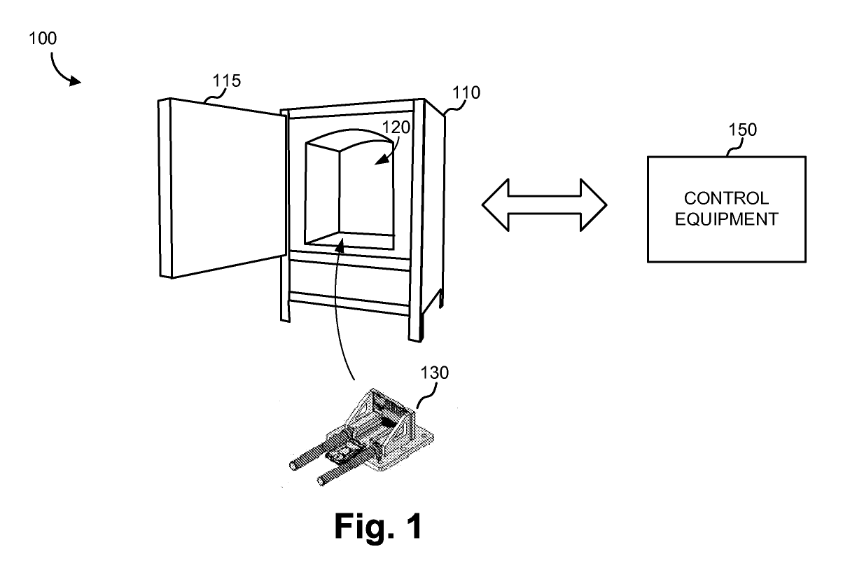

FIG. 1 is a diagram of an exemplary system 100 in which concepts described herein may be implemented. System 100 may include a testing chamber 110. Testing chamber 110 may include a structure that includes an internal chamber 120 that can be heated to a user-specified temperature. Testing chamber 110 may include a door 115 that may be used to seal a testing apparatus 130 inside of chamber 120 during testing. Testing chamber 110 may be heated using, for example, a gas or electric heater. Testing chamber 110 may additionally include one or more electrical and/or mechanical connections or ports for connecting testing apparatus 130 to control equipment 150. Control equipment 150 may be located outside of testing chamber 110 and may provide signals to or receive signals from testing apparatus 130.

Control equipment 150 may also be used to monitor information relating to the testing. In alternative implementations, control equipment 150, or portions of control equipment 150, may be located inside testing chamber 110, such as control equipment integrated with testing apparatus 130.

An electronic device that is to be tested, such as a printed circuit board (PCB), may be inserted into testing apparatus 130 and then both testing apparatus 130 and the PCB may be placed in chamber 120. Testing apparatus 130 may include electronic circuitry for interfacing with and testing the PCB. Testing apparatus 130 may include mechanical and electrical connections that may be connected, through testing chamber 110, to control equipment 150. In this manner, testing apparatus 130 may be externally controlled and tested at a user-specified temperature inside of testing chamber 110.

When testing the device, the operating temperature limits may be defined by a surface temperature as well as surrounding ambient air temperature. In some cases, these temperature values can be the same which can present a problem: when an electronic device is powered on, it begins to produce heat, its temperature begins to rise and since the electronic device is already at equilibrium with the ambient air it will get hotter than the ambient air and exceed the surface temperature limit. Therefore, during testing, a measure of control over the surface temperature should be implemented to keep the electronic device at the same value as the ambient air temperature. System 100 may be used to test the device while keeping the device at the same temperature as the ambient air temperature.

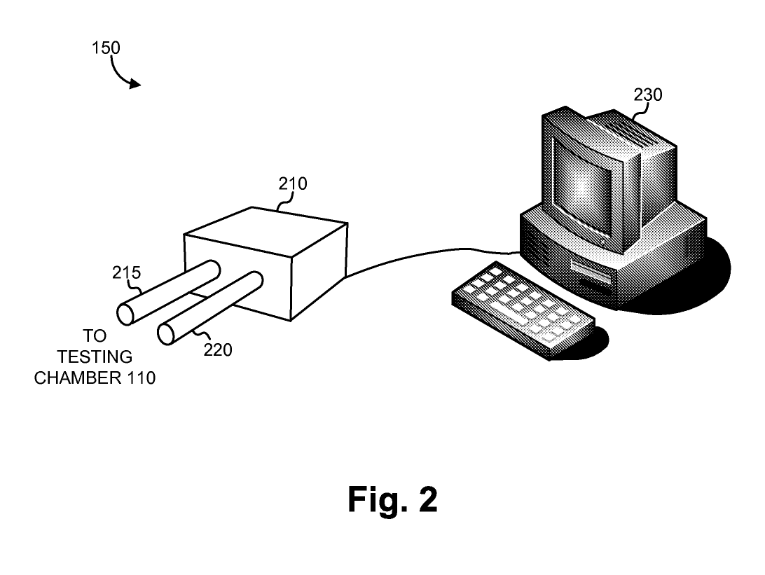

FIG. 2 is a diagram illustrating an exemplary implementation of the control equipment shown in FIG. 1. Control equipment 150 may include air mover unit 210 and computing device 230. Air mover unit 210 may generally include one or more fans and associated control circuitry for controlling the fans. Air mover unit 210 may be connected to one or more air ducts, such as ducts 215 and 220, that lead to testing chamber 110. In operation, air mover unit 210 may include, for example, fans that blow air, such as room temperature air, into testing chamber 110 and over heat exchanger rails in the testing chamber. Air mover unit 210 may be controlled or monitored through computing device 230.

Computing device 230 may include, for example, a laptop or personal computer.

Although FIG. 2 shows exemplary components of control equipment 150, in other implementations, control equipment 150 may contain fewer, different, differently arranged, or additional components than depicted in FIG. 2.

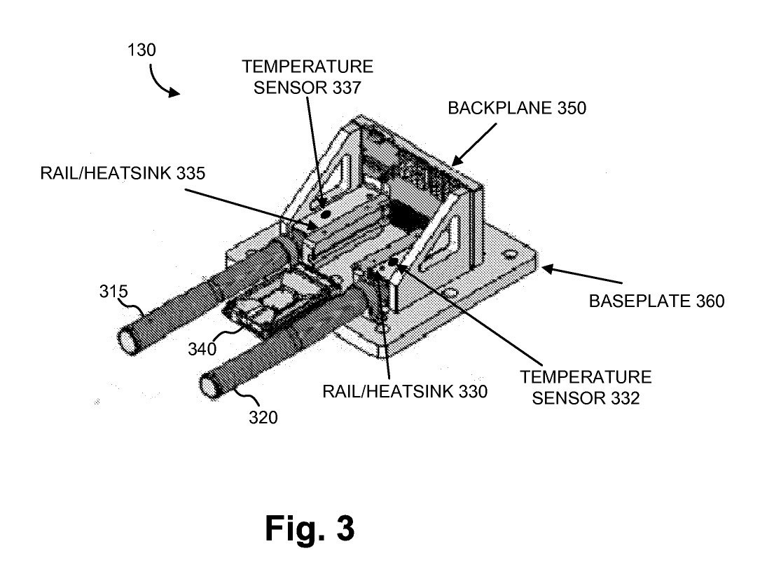

FIG. 3 is a diagram illustrating an exemplary implementation of testing apparatus 130. As previously mentioned, testing apparatus 130 may be designed to hold an electronic device, such as a PCB, during testing within testing chamber 110. A PCB enclosed in a thermal case is particularly illustrated in FIG. 3 as PCB package 340, which is being inserted into testing apparatus 130.

Testing apparatus 130 may include inlet hoses 315 and 320, rail/heat exchanger 330 and 335, backplane 350, and base plate 360. Additionally, temperature sensors 332 and 337 may be located on rails/heat exchanger 330 and 335. Inlet hoses 315 and 320 may connect to air ducts 215 and 220, respectively, of fan unit 210 and may carry a coolant, such as fan blown air, into testing chamber 110. Inlet hose 315 may be particularly configured to blow air over rail/heat exchanger 335. Rail/heat exchanger 335 may include a rail into which PCB package 340 may be slideably inserted and a heat exchanger that may be attached to or integrated as part of the rail. Rail/heat exchanger 335 may be formed from a metal, such as copper or aluminum, that is a relatively good thermal conductor. Rail/heat exchanger 335 may thus tend to transfer heat away from PCB package 340 and air blown from inlet hose 315 may be blow over rail/heat exchanger 335 to thus remove the heat from rail/heat exchanger 335. Inlet hose 320 and rail/heat exchanger 335 may be configured similarly to inlet hose 315 and rail/heat exchanger 330. That is, rail/heat exchanger 330 may hold PCB package 340 and act as a heat conductor that transfers heat from PCB package 340 to rail/heat exchanger 330, where the heat may be dissipated by the air blown through inlet hose 320.

Temperature sensors 332 and 337 may be positioned to measure the temperature of PCB package 340. The temperature sensors may be located, for example, on rails/heat exchanger 330 and 335. Temperature sensors 332 and 337 may include thermistors or other types of sensors.

Backplane 350 of testing apparatus 130 may include an electrical interface to PCB package 340. Control and power signals may be transferred through backplane 350 to circuitry external to testing chamber 110, such as fan unit 210 and/or computing device 230. For instance, temperature values measured by temperature sensors 332 and 337 may be transmitted through backplane 350 to air mover unit 210. Alternatively, the temperature values measured by temperature sensors 332 and 337 may be independently transmitted to air mover unit 210, such as by separate sets of wires. Baseplate 360 may include a substantially flat base that supports testing apparatus 130. Rails/heat exchangers 330 and 335, and backplane 350, may be attached to baseplate 360. As illustrated, baseplate 360 may include holes through which base plate may be fixedly attached to testing chamber 110.

Although FIG. 3 shows exemplary components of testing apparatus 130, in other implementations, testing apparatus 130 may contain fewer, different, differently arranged, or additional components than depicted in FIG. 3.

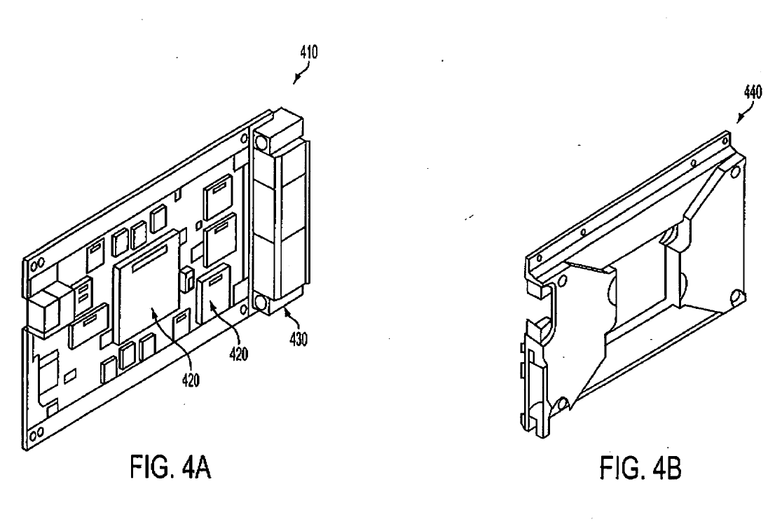

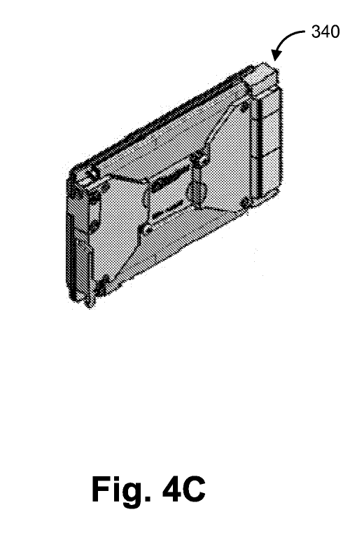

FIGS. 4A-4C are diagrams illustrating an exemplary implementation of PCB package 340. More particularly, FIG. 4A illustrates an exemplary PCB; FIG. 4B illustrates an exemplary thermal plate that may be attached to the PCB shown in FIG. 4A; and FIG. 4C illustrates PCB package 340 after the PCB shown in FIG. 4A is attached to the thermal plate shown in FIG. 4B.

As shown in FIG. 4A, a PCB 410 may include a number of components 420, such as, for example, semiconductor integrated chips, resistors, capacitors, and/or inductors. PCB 410 may also include an electrical interface 430, which may include signal and power connections through which PCB 410 may connect to an external system or, during testing, to backplane 350. During temperature testing, it may be desirable to test the operation of the components of PCB 410. For example, signals that are designed to fully use components 420 may be applied to PCB 410 and the response of PCB 410, at a particular temperature, may be observed.

In one possible implementation, PCB 410 may be a network device, such as a router that is to be employed in a conduction cooled closed-system environment, in which the system may be sealed to prevent contamination with external dust, etc.

FIG. 4B is a diagram illustrating an exemplary thermal plate 440. Thermal plate 440 may be designed to be coupled with PCB 410. Thermal plate 440 may be made of a conductive material, such as aluminum or copper. In some implementations, a thermally conductive grease may be applied at the interface points between PCB 410 and thermal plate 440, such as on top of components 420.

FIG. 4C is a diagram illustrating PCB 410 and thermal plate 440 when assembled as PCB package 340. PCB 410 and thermal plate 440 may be secured together using, for example, one or more screws. PCB package 340 may be inserted into rails/heat exchangers 330 and 335 of testing apparatus 130. With PCB package 340, heat generated by PCB 410 may be transferred through thermal plate 440 and into rails/heat exchangers 330 and 335.

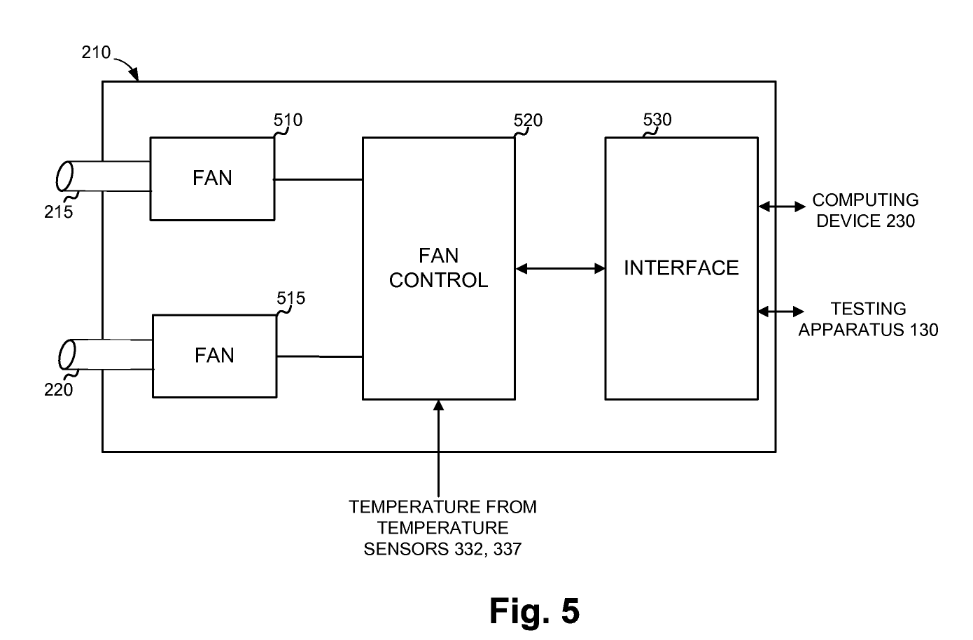

FIG. 5 is a block diagram illustrating an exemplary implementation of air mover unit 210. Air mover unit 210 may include fans 510 and 515, fan control logic 520, and interface logic 530. Additionally, air mover unit 210 may receive temperature signals from temperature sensors 332 and 337. Air mover unit 210 may additionally connect to computing device 230 and/or testing apparatus 130 to communicate other signals, such as control or power signals. Fans 510 and 515 may include fans designed to blow cool air, such as room temperature air from outside of test chamber 110, into test chamber 110 via ducts 215 and 220. Fans 510 and 515 may each be variable speed fans that are controlled by fan control logic 520. Fan control logic 520 may receive the measured temperature values from temperature sensors 332 and 337. Based on the received temperatures, fan control logic 520 may control the speed of fans 510 and 515 in order to keep the temperature of PCB package 340 at the desired surface temperature. For example, if the desired surface temperature of PCB 410 is set at 85° C., and the temperature of the heat exchanger associated with fan 510 is 85° C., fan control logic 520 may turn off or significantly turn down the speed of fan 510. If the temperature of the heat exchanger associated with fan 510 begins to rise, however, fan control logic 520 may turn up the speed of fan 510. In general, fan control logic 520 may operate to vary the speeds of fans 510 and 515 to keep the corresponding temperature values as close as possible to the desired value of PCB package 340.

Fan control logic 210 may additionally include interface logic 530, which may act as an interface for signals communicated with computing device 230. Through interface logic 530, a user of computing device 230 may, for example, receive the temperatures received by fan control logic 520, directly control fan control logic 520, or generate other signals for transmission to test chamber 110, such as signals used to interact with PCB 410.

In some implementations, fan unit 210 may not connect to computing device 230. In this case, fan unit 210 may include, for instance, an input mechanism, such as a keypad through which the user may input the desired control temperature.

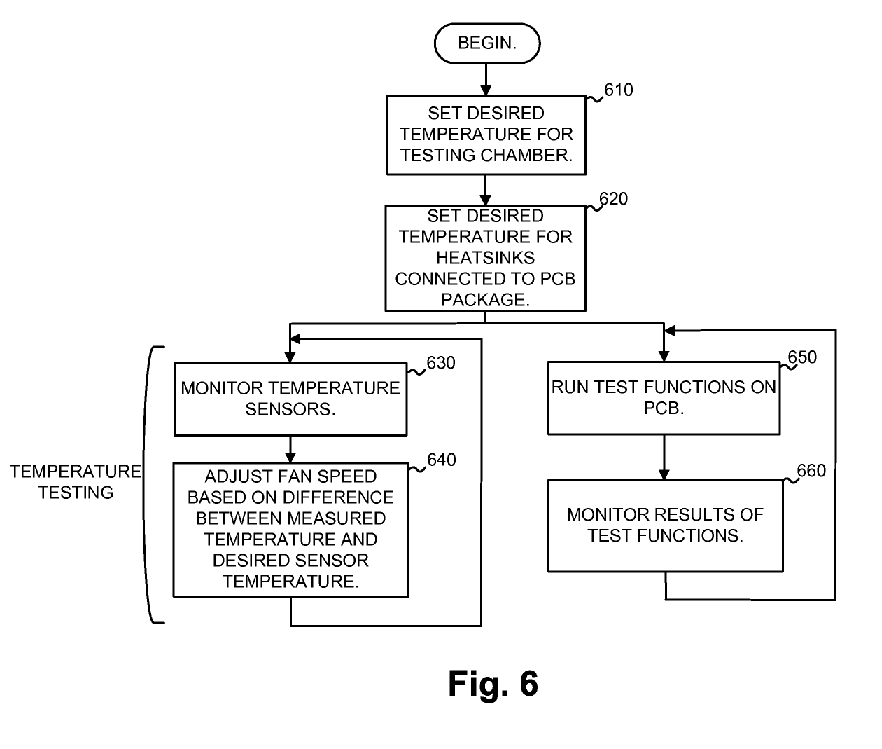

FIG. 6 is a flow chart illustrating exemplary operations for performing a high temperature test of an electronic device.

A user may set the desired temperature for testing chamber 110 (block 610). Testing chamber 110 may include, for example, an integrated control panel through which the desired temperature may be set. Alternatively, the temperature of testing chamber 110 may be remotely set by the user, such as through computing device 230. Generally, the desired temperature may be set to a temperature at which stress testing of the electronic device is to be performed. For example, if the specification for an electronic device calls for the device to reliably function up to a maximum ambient air temperature of 85° C., the desired temperature for testing chamber 110 may be set at 85° C.

The desired temperature for the heat exchangers connected to PCB package 340 (e.g., rails/heat exchangers 330 and 335) may also be set (block 620). This temperature may be set, for example, in air mover unit 210. Air mover unit 210 may generally operate to vary the speed of fans 510 and 515 to keep the rails/heat exchangers 330/335 at the desired temperature. In a typical operation, the desired temperature for the heat exchangers may be set to be equal to the desired temperature of testing chamber 110.

When the desired temperatures for testing chamber 110 and rails/exchangers 330 and 335 are set, high temperature stress testing of PCB 410 may begin. During testing, air mover unit 210 may continually monitor temperature sensors 332 and 337 (block 630) and adjust the operation of fans 510 and 515 based on the current temperature readings (block 640). More specifically, fan control logic 520 may adjust fans 510 and 515 based on the difference between the measured temperatures and the desired temperatures of rails/heat exchangers 330 and 335. In general, as the temperatures of rails/heat exchangers 330 and 335 increase above the desired temperature, fan control logic 520 may increase the speed of fans 510 and/or 515 to blow an increasing volume of cooler (e.g., room temperature) air over rails/heat exchangers 330/335. Techniques for implementing feedback control loops to minimize an error signal (e.g., the difference between the desired and measured temperature) are generally known and will not be described in additional detail herein.

During the high temperature stress testing, PCB 410 may be operated. In one implementation, test functions or a test suite may be run on PCB 410 (block 650). The test functions may include functions designed to simulate the use of PCB 410 when deployed in the final system. For example, in some designs of PCB 410, this may involve simply turning on PCB 410. In other situations, PCB 410 may be loaded with software designed to test the elements of PCB 410 or computing device 230 may provide control signals to PCB 410 in order to test various elements of PCB 410.

The results of the test functions may be monitored or recorded (block 660). In some implementations, the output of PCB 410 may be received by computing device 230 and compared to an expected output to determine if PCB 410 continues to operate correctly under temperature stress. In other implementations, additional sensors may be installed on PCB 410, such as sensors monitoring individual components 420, and monitored to ensure the values measured by the sensors are within acceptable ranges. In some implementations, the results may be monitored in real-time by computing device 230 during the course of the test. In other possible implementations, testing apparatus 130 may record results relating to the test, which may then be analyzed after the test.

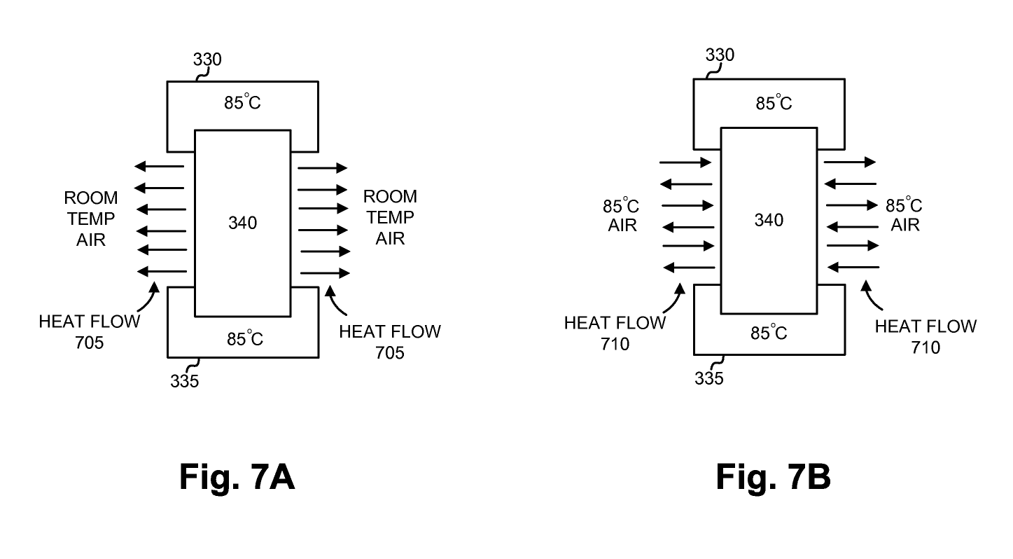

FIGS. 7A and 7B are diagrams conceptually illustrating heat flow for a testing apparatus.

In FIG. 7A, PCB package 340 is in contact with heat exchangers/rails 330 and 335. Assume that in this situation, the ambient temperature surrounding PCB package 340 is at room temperature, which may be significantly less than the desired test temperature. This may be the case when PCB package 340 is tested without using a heating chamber. PCB package 340, due to heat generated by the operation of PCB 410, may still attain the desired test surface temperature (e.g., 85° C.). However, because the ambient air temperature may be less than the temperature of PCB package 340, heat may transfer at a higher rate from PCB package 340 into the ambient air, as illustrated by arrows 705. The situation illustrated in FIG. 7A may happen in a heat stress test setup in which heat exchangers/rails 330 and 335 may be cooled to the desired maximum temperature but the test is conducted at room temperature. This setup may not accurately correspond to a deployed version of the system in which the external temperature may be as high as the temperature of heat exchangers/rails 330 and 335. This type of deployed setup may occur, for example, in an enclosed electronic system.

In FIG. 7B, PCB package 340 may be in contact with heat exchangers/rails 330 and 335. Assume that in this situation, the ambient temperature surrounding PCB package 340 is kept at a user designated temperature (e.g., 85° C.). The ambient temperature may be kept at the user designated temperature consistent with aspects described herein using testing chamber 110. Because the ambient air temperature may be set to be equal to the temperature of heat exchangers/rails 330 and 335, no net (extra) heat transfer may occur between PCB package 340 and the ambient air. This is illustrated by heat flow arrows 710. This setup may accurately correspond to a deployed version of the system in which the external temperature may be as high as temperature of heat exchangers/rails 330 and 335, such as may occur in an enclosed electronic system.

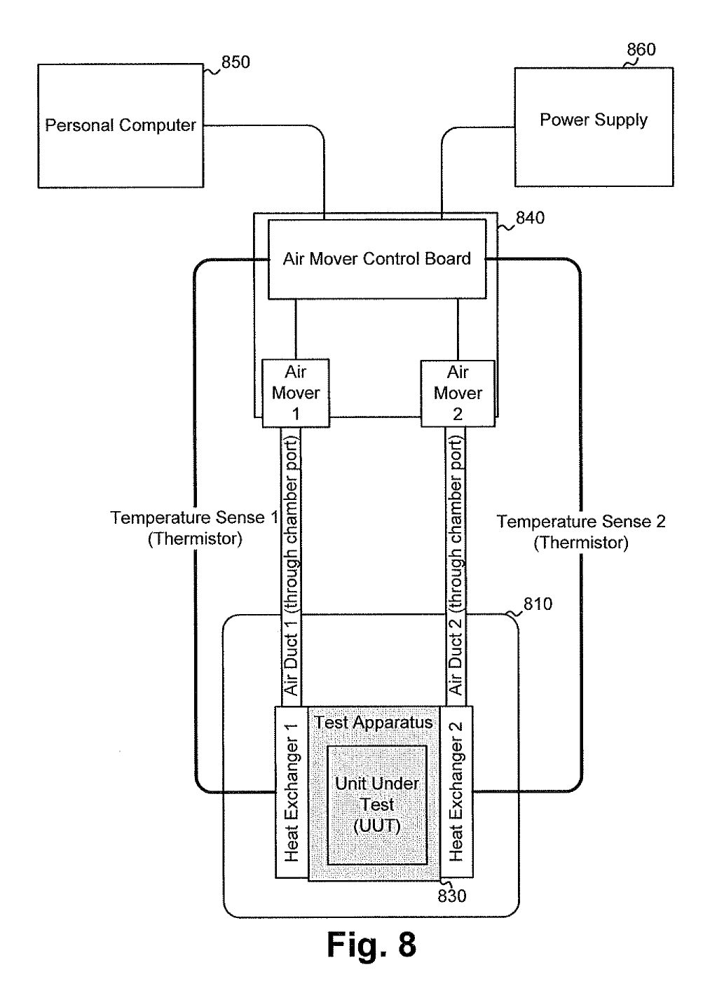

FIG. 8 is a diagram schematically illustrating a complete test system constructed consistent with aspects described above. A testing chamber 810, such as testing chamber 110, may include a test apparatus 830, similar to test apparatus 130. Test apparatus 830 may include heat exchangers, labeled as heat exchangers 1 and 2, designed to transfer heat from the unit under test (UUT) (e.g., PCB package 340). Air ducts, labeled as air ducts 1 and 2 may lead from the heat exchangers to an air mover unit 840. Additionally, temperature sensors, such as thermistors, may be attached to heat exchangers 1 and 2 and may be connected to air mover unit 840 via wires that lead out of testing chamber 810.

Air mover unit 840 may include an air mover control board, such as fan control unit 520, that controls, based on signals from the temperature sensors, air movers 1 and 2. Each of the air movers may be, for example, fans.

As is also shown in FIG. 8, a personal computer 850 may control air mover unit 840. Personal computer 850 may be particularly used to set the target temperature for the UUT. A power supply may provide power to air mover unit 840.

With the system shown in FIG. 8, the air temperature inside of testing chamber 810 may be controlled and the surface temperature of the UUT controlled. In this manner, heat egress from the UUT can be simulated under very accurate worst-case temperature conditions.

### CONCLUSION

As described above, a high temperature testing system for an electronic device may include a testing chamber in which the temperature of the ambient air in the testing chamber may be maintained at a desired testing temperature. The device to be tested may be tested inside the chamber while external air, such as room temperature air, may be blown over a heat exchanger associated with the device to thereby keep the device at the set desired surface temperature.

The foregoing description of implementations provides illustration and description, but is not intended to be exhaustive or to limit the invention to the precise form disclosed. Modifications and variations are possible in light of the above teachings or may be acquired from practice of the invention.

For example, while series of acts have been described with regard to FIG. 6, the order of the acts may be varied in other implementations consistent with the invention. Moreover, non-dependent acts may be implemented in parallel.

It will also be apparent that aspects described herein may be implemented in many different forms of software, firmware, and hardware in the implementations illustrated in the figures. The actual software code or specialized control hardware used to implement aspects described herein is not intended to limit the scope of the invention. Thus, the operation and behavior of the aspects were described without reference to the specific software code—it being understood that software and control hardware can be designed to implement the aspects based on the description herein.

Further, certain aspects described herein may be implemented as “logic” or as a “component” that performs one or more functions. This logic or component may include hardware, such as an application specific integrated circuit or a field programmable gate array, or a combination of hardware and software.

No element, act, or instruction used in the description of the invention should be construed as critical or essential to the invention unless explicitly described as such. Also, as used herein, the article “a” is intended to include one or more items. Where only one item is intended, the term “one” or similar language is used. Further, the phrase “based on” is intended to mean “based, at least in part, on” unless explicitly stated otherwise.

What is claimed is:

1. A system for testing an electronic device, the system comprising:
an air mover unit including:
a fan,
logic to control operation of the fan based on a temperature signal received by the air mover unit, the temperature signal indicating a temperature associated with the electronic device, and
an outlet hose connected to an output of the air mover unit to carry air blown by the fan;
a testing apparatus including:
an inlet hose connected to receive the air blown through the outlet hose,
a heat exchanger connected to the inlet hose such that the blown air is passed over the heat exchanger to cool the heat exchanger, the heat exchanger additionally configured to hold the electronic device that is being tested, and
a temperature sensor attached to the heat exchanger, the temperature sensor generating the temperature signal that is received by the air mover unit; and
a testing chamber including a chamber to hold the testing apparatus and a heater to heat the testing chamber to a user designated temperature during testing of the electronic device.

2. The system of claim 1, where,
the air mover unit further includes
at least one second fan, and
at least one second outlet hose connected to an output of the second fan to carry air blown by the at least one second fan; and
where the testing apparatus further includes
at least one second inlet hose connected to receive the air blown through the at least one second outlet hose,
a second heat exchanger connected to the at least one second inlet hose such that the blown air is passed over the at least one second heat exchanger to cool the at least one second heat exchanger, the at least one second heat exchanger additionally configured to hold the electronic device that is being tested, and
at least one second temperature sensor attached to the at least one second heat exchanger, the at least one second temperature sensor generating at least one second temperature signal that is received by the air mover unit.

3. The system of claim 1, where the logic to control operation of the fan based on the temperature signal received by the air mover unit increases or decreases an operating speed of the fan based on a difference between a value of the temperature signal and a user designated temperature of the electronic device.

4. The system of claim 1, where the heat exchanger further includes:
rails through which the electronic device is slideably inserted into the heat exchanger.

5. The system of claim 1, where the electronic device includes a printed circuit board enclosed in a thermally conductive case.

6. The system of claim 1, where the temperature sensor includes a thermistor.

7. The system of claim 1, where the testing apparatus further includes:
a backplane that includes an electrical connection for the electronic device.

8. The system of claim 7, where the testing apparatus further includes:
a baseplate connected to the heat exchanger and the backplane, the baseplate coupling the testing apparatus to the testing chamber.

9. A method for testing an electronic device, the method comprising:
maintaining a first air temperature, within a testing chamber that includes the electronic device, the electronic device including a heat exchanger to dissipate heat generated by the electronic device;
setting, in a control unit, a desired surface temperature of the electronic device;
controlling, by the control unit, cooling of the heat exchanger to maintain the electronic device at the desired surface temperature of the electronic device, the cooling including blowing room temperature air from outside of the testing chamber over the heat exchanger, where the temperature of the room temperature air is less than the first air temperature;
testing operation of the electronic device while the electronic device is within the testing chamber; and
transmitting results of the testing of the electronic device to a computing device located externally to the testing chamber.

10. The method of claim 9, where the electronic device includes a printed circuit board enclosed in a thermally conductive case.

11. The method of claim 9, where testing the operation of the electronic device includes running a suite of test functions on the electronic device.

12. The method of claim 9, where controlling cooling of the heat exchanger further includes:
controlling an operating speed of a fan.

13. The method of claim 12, where controlling cooling of the heat exchanger further includes:
receiving, by the control unit, a temperature of the electronic device.

14. The method of claim 13, where controlling cooling of the heat exchanger further includes:
controlling the operating speed of a fan based on a difference between the temperature of the electronic device and the desired temperature of the electronic device.

15. A device comprising:
a baseplate;
a rail attached to the baseplate, the rail being formed of thermally conductive material, the rail being formed to secure a printed circuit board (PCB) case;
a heat exchanger connected to the rail and the baseplate, the heat exchanger being formed of thermally conductive material;
a backplane connected to the baseplate, the backplane include an electrical connection to form an electrical interface with the PCB case when the PCB case is inserted into the rail;
an inlet hose connected to deliver air blown from an external source to the heat exchanger; and
a temperature sensor attached to the heat exchanger, the temperature sensor generating a temperature signal that is used to control an amount of air delivered via the inlet hose.

16. The device of claim 15, where the air blown from an external source includes air at a lower temperature than air surrounding the device.

17. The device of claim 15, where the rail provides a slot through which the PCB case is slideably inserted.

18. The device of claim 15, further including:
a second rail attached to the baseplate; and
a second heat exchanger connected to the second rail and the baseplate.

19. A device comprising:
means for maintaining a first air temperature within a chamber that includes an electronic device, the electronic device including a heat exchanger to dissipate heat generated by the electronic device;
means for setting a desired surface temperature of the electronic device;
means for controlling cooling of the heat exchanger to maintain the electronic device at the desired temperature of the electronic device, the cooling including blowing room temperature air from outside of the chamber over the heat exchanger, where the temperature of the room temperature air is less than the first air temperature;
means for testing operation of the electronic device while the electronic device is within the chamber; and
mean for transmitting results of the testing of the electronic device to a computing device located externally to the chamber.

20. The device of claim 19, where the electronic device includes a printed circuit board enclosed in a thermally conductive case.
